(19) United States
(12) Patent Application Publication
(10) Pub. No.: US 2024/0266803 A1
(43) Pub. Date: Aug. 8, 2024

(54) ALIGNMENT OF A LASER CHIP AND ANOTEHR CHIP USING A SELECTIVE COUPLER

(71) Applicant: DustPhotonics, Modiin (IL)

(72) Inventors: Yoel Chetrit, Kfar Ben Nun (IL); Israel Weiss, Jerusalem (IL)

(73) Assignee: DustPhotonics, Modiin (IL)

(21) Appl. No.: 18/434,708

(22) Filed: Feb. 6, 2024

Related U.S. Application Data
(60) Provisional application No. 63/483,516, filed on Feb. 6, 2023.

(51) Int. Cl. H01S 5/14; H01S 5/40

(52) U.S. Cl. CPC H01S 5/141; H01S 5/4087

(57) ABSTRACT

A method for operating multiple chip regions. The method includes aligning the multiple chip regions using first wavelength band signals, and conveying transmission signals of a second wavelength band signals. The multiple chip regions may be without a second wavelength band transmitter and include a path for receiving the second wavelength band signals from another chip.

### CROSS REFERENCE

This application claims priority from U.S. provisional patent Ser. No. 63/483,516 filing date Feb. 6, 2023, which is incorporated herein by reference.

### BACKGROUND

There is a need to accurately align a laser chip and a Si chip which are used in SiP technology as building blocks for design and fabrication of Photonic integrated Circuits, PICs. In the related designs, the laser chips, consist a laser waveguide which enables to output the laser radiation into a waveguide on the Si chip. To achieve an effective coupling for the laser radiation, the corresponding waveguides on laser and Si chips must be properly aligned. In general, the Si chip comprises the other photonic integrated circuit (PIC), which are driven by the laser's optical signal to achieve a specific functionality of a certain required application.

The activation of the laser chip during an alignment process to a Si chip is costly, complicated, and problematic, especially for devices which are manufactured in mass production. Hence there is a growing demand for methods which doesn't required the laser activation which are defined as passive alignment methods.

Generally, in these alignment methods it is required to fabricate additional elements such as waveguides, marks and other elements on both the laser and Si die parts. The manufacturing cost of these additional elements on the laser dies are significantly higher than on the Si die part. Hence a simplification of either the processing and or die sizes can have a much higher impact on the manufacturing cost of an assembly of PIC circuits composed out of a Laser chip and Si chip.

Hence there is a high motivation to develop such alignment methods which can simplify the alignment process and reduce manufacturing cost of the laser die/chip. Furthermore, there is a high motivation to develop such alignment methods which will have almost no impact on the related PIC circuit performance, composed of an assembly laser and Si chips.

### BRIEF DESCRIPTION OF THE DRAWINGS

FIG. 1 is an example of a system;

FIG. 2 is an example of a system;

FIG. 3 is an example of a part of an electrooptic chip of the system;

FIG. 4 is an example of a part of an electrooptic chip of the system;

FIG. 5 is an example of a part of an electrooptic chip of the system;

FIG. 6 is an example of a method;

FIG. 7 is an example of a method;

FIG. 8A illustrates an example of multiple chip regions;

FIG. 8B illustrates an example of multiple chip regions;

FIG. 8C illustrates an example of multiple chip regions;

FIG. 9 illustrates an example of multiple chip regions;

FIG. 10 illustrates an example of a method;

FIG. 11 illustrates an example of a method;

FIG. 12 illustrates an example of a method;

FIG. 13 illustrates an example of multiple chip regions;

FIG. 14 illustrates an example of a cascading of chips;

FIG. 15 illustrates an example of a cascading of chips;

FIG. 16 illustrates an example of multiple chip regions; and

FIG. 17 illustrates an example of a cascading of chips.

### DETAILED DESCRIPTION OF THE DRAWINGS

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any reference in the specification to a method should be applied mutatis mutandis to a device or system capable of executing the method.

Any reference in the specification to a system or device should be applied mutatis mutandis to a method that may be executed by the system.

Any combination of any module or unit listed in any of the figures, any part of the specification and/or any claims may be provided.

Any combination of any steps of any method illustrated in the specification and/or drawings may be provided.

Any combination of any subject matter of any of claims may be provided.

Any combinations of systems, units, components, processors, sensors, illustrated in the specification and/or drawings may be provided.

There is provided a method and a system for passive alignment between a laser chip and an electrooptic chip, the electrooptic chip may include one or more optical elements configured to receive radiation from the laser chip, without a requirement for the laser activation and without requiring to use costly alignment equipment such as optical backscatter reflectometers that are very expensive and have very slow mode of operation.

The alignment electrooptic chip may include a Wavelength Selective Coupler (WSC) that is configured to define a first WSC optical path between the laser chip and a first part of the electrooptic chip and to define a second WSC optical path between the laser chip and a second part of the electrooptic chip.

The first part of the electrooptic chip may be or may include alignment circuitry.

The second part of the electrooptic chip may be or may include an electrooptic unit such as a photonic integrated circuit (PIC).

The second part may also be referred to as an operational part, a main part, a functional part, or a post-alignment part of the electrooptic chip.

The first WSC path and at least some of the components of the first part of the electrooptic chip form a first optical path that is utilized during the alignment process.

The first optical path may be configured to convey radiation (also referred to as probe radiation) within a first wavelength range—and may be centered about a first wavelength.

The first optical path may be used to convey radiation from a radiation source (also referred to as alignment radiation source) located within the electrooptic chip. The alignment radiation source may be external to the electrooptic chip—and the electrooptic chip may be optically coupled to the alignment radiation source and configured to convey the radiation of the alignment radiation source through the first optical path to the laser chip.

The first optical path may include the laser waveguide or may use a different waveguide (for example an auxiliary waveguide) of the laser chip.

The second WSC path and at least some of the components of the second part of the electrooptic chip form a second optical path that may be utilized after the completion of the alignment process.

The second optical path may be configured to convey radiation of a second wavelength range—and may be centered about a second wavelength.

The first wavelength may differ from the second wavelength.

The first wavelength range may differ from the second wavelength range. The first and second wavelength ranges may be non-overlapping.

The first and second wavelength ranges may be distance from each other to enable the WSC to easily differentiate between them.

Due to the wavelength selective behavior of the WSC (which differentiates between the first and second wavelength ranges), there may be no need to move the electrooptic chip in relation to the laser chip once alignment is obtained.

The second optical path may be used to convey radiation from the laser chip to the electrooptic chip.

Using the WSC during alignment allows wafer level pick and place process using coupling to grating couplers. This allows an alignment method that does not depend (as in an Optical Backscatter Reflectometry (OBR) based method) on the electrooptical unit design and application. It may also be used in a high loss electrooptical unit—which may be problematic with the OBR based method. The OBR based involves using a very expensive OBR measurement device and complicated and slow scan mode. See, for example Flip-chip Integration of InP to SiN Photonic Integrated Circuits, M. Therurer Et el, Journal of Lightwave Technology, Vol. 38, No. 9, May 2020.

The first path may include a coupler such as a grating coupler. Such a coupler may or may not be provided in the second path.

The second path may be regarded as the operational path or main path or functional path or post-alignment path of the system—and it may exhibit lower losses than the first path.

The second path may be independent from the first path—so that any energy penalty occurring during the alignment process may not affect the passage of radiation through the second path.

The method may include performing a Back Reflection setup measurement, for example—obtaining a single readout (or a few readouts), using special PIC design with external source and power meter. This allows a very fast scan of placement and alignment. This is in contrary of using OBR based method—that requires sweeping wavelengths on every location—that is a very time consuming process at each location and requires analysis of OBR data.

During the alignment, the laser chip is illuminated with radiation over the first path—and reflect back reflected radiation over the first path. The reflection can be mainly (almost only) from a laser waveguide of the laser chip (minor reflection can be from the WSC). Allowing one readout method. This is in contrary to the OBR based method. This method may be applied for an electrooptic chip having any electrooptical unit any electrooptic chip, even with high losses. This is in contrary of using the OBR based method that suffers from having reflections from various components such as free space, electrooptical components, laser, that require using OBR.

The method may avoid the activation of the laser which is costly and complicated for high volume manufacturing of these device. Furthermore, in the disclosed method the first waveguide is aligned directly to a laser waveguide with almost no requirements for additional passive alignment elements on the laser die part. This results in a highly accurate passive method which have accuracy similarly to active alignment method.

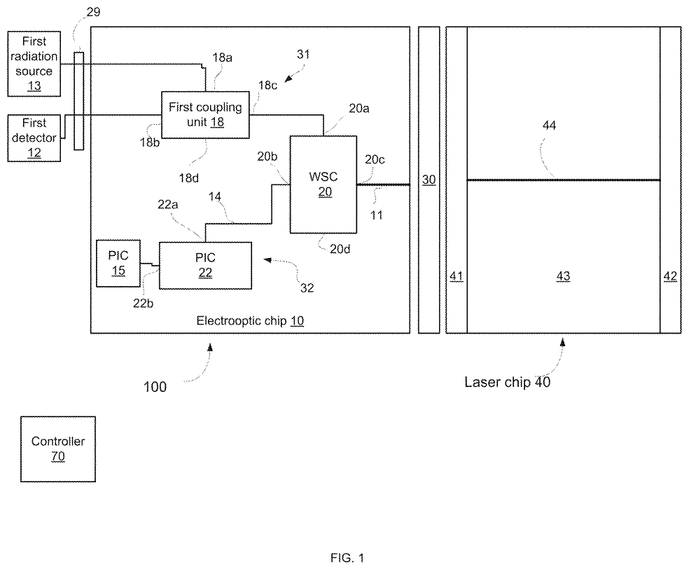

FIG. 1 illustrates a system 100 that includes laser chip 40, electrooptic chip 10, and Index Matching Layer (IML) 30.

A first detector 12 and a first radiation source 13 may also be included in system 100. The first detector 12 and the first radiation source 13 may be located outside the electrooptic chip 10 (as shown in FIG. 1) but at least one of them may belong to the electrooptic chip 10.

The first detector 12 and the first radiation source 13 may be optically coupled to the electrooptic chip in various manner—for example by a fiber array 29 that includes spaced apart fibers (illustrates as lines that pass through the rectangle denoted 29).

It should be noted that the system 100 may not include IML 30.

The laser chip 40 includes a laser waveguide 44 located at a top of the laser diode body/chip 43, and is illustrated as having a distal reflective element such as high reflective coating layer 42, and a proximal reflective element such as low reflective coating layer 41.

The low reflective coating layer 41 may be an Anti-Reflective Coating (ARC) layer designed reduce the internal reflections from the laser chip output facet back into the laser chip.

The distal reflective element may be a wavelength selective element (for example—be a Low Bandwidth Reflective Layer) that is configured to have a high reflectivity in the first wavelength range and have low reflectivity in the second wavelength range.

The electrooptic chip 10 may include WSC 20, first part 31, and second part 32.

First part 31 may include first coupling unit 18.

The first radiation source 13 is optically coupled via a fiber and via a port of the electrooptic chip 10 to a first port 18a of the first coupling unit 18.

The first detector 12 is optically coupled via another fiber and via another port of the electrooptic chip 10 to a second port 18b of the first coupling unit 18.

A third port 18c of the first coupling unit 18 is optically coupled to a first WSC port 20a of WSC 20.

A fourth port 18d of the first coupling unit is grounded or otherwise ignored of. —

Second part 32 includes an electrooptical unit such as photonic integrated circuit (PIC) 22. PIC 22 may include a receiver, may include transmission path optics, may be a sensor, a modulator, a bio sensor, or any other PIC.

A first port 22a of PIC 22 is optically coupled to a second WSC port 20b of WSC 20 via PIC waveguide 14.

A second port 22b of PIC 22 may be optically coupled to any other unit—such as post-PIC unit 15.

A third port 20c of WSC 22 is optically coupled to first waveguide 11.

A fourth port 20d of WSC 22 is grounded or otherwise ignored of.

The following examples illustrates the progress of signals through the system. The passage may amend any signal—for example reduce the intensity of the signal, add noise or perform any other operation. For simplicity of explanation the same term is used to describe the signal throughout the progress.

During the alignment process a probe signal 61 is
a. Generated by first radiation source 13.
b. Received by first port 18a of first coupling unit 18.
c. Passes through the first coupling unit 18 and outputted from the third port 18c of the first coupling unit 18.
d. Received by first port 20a of WSC 20.
e. Provided by a first WSC optical path to third port 20c of WSC.
f. Outputted (from third port 20c) to the first waveguide 11.
g. Transmitted towards the laser chip 40—may pass through IML 30.

When the first waveguide 11 is aligned with the laser waveguide 44, then the probe signal 61 also passes through the laser waveguide and is reflected from the distal reflective element to provide a reflected probe signal 62.

The reflected probe signal 62:
a. Propagates over the laser waveguide 44 to the first waveguide 11.
b. Propagates along first waveguide 11.
c. Enters the third port 20c of WSC.
d. Provided by the first WSC optical path to first port 20a of WSC.
e. Received by third port 18c of first coupling unit 18.
f. Passes through the first coupling unit 18 and is outputted from the second port 18b of the first coupling unit 18.
g. Detected by first detector 12.

When the first waveguide 11 is not aligned with the laser waveguide 44, then the probe signal 61 may be barely (and even insignificantly) reflected from proximal reflective element to provide the reflected probe signal.

In any case—it is expected that the reflected probe signal 62 from an aligned laser chip significantly differs from the reflected probe signal 62 from an unaligned laser chip—thereby allowing to determine whether the lase chip is aligned (with the electrooptic chip).

The detection signals of first detector 12 may be processed by a controller 70 to assist in the alignment process.

The controller 70 may control the spatial relationship between the laser chip 40 and the electrooptic chip 100—for example by controlling or requesting the movement of one (or both) of the chips until an alignment stop condition is fulfilled—for example—an alignment is obtained, the alignment failed, a predefined number of alignment iterations were executed, and the like.

For example—one or more chip of the electrooptic chip and the laser chip can be mechanically manipulated—for example along x,y-directions, with a sufficiently large spatial resolution. The mechanical manipulation can be done along a plane that is perpendicular to the optical axis of the laser waveguide. It should be noted that at the start of the alignment process the electrooptic chip and the laser chip may be roughly aligned.

During the alignment process, the strength of the reflected probe signal may provide an indication of the degree of alignment—for example—stronger reflected probe signal can indicate of a better alignment.

The probe signal 61 and the reflected probe signal 62 pass through the first optical path.

During an operational mode, the laser chip 40 outputs a laser signal 63 that is:
a. Received by the first waveguide 11.
b. Enters the third port 20c of WSC.
c. Provided by the second WSC optical path to second port 20b of WSC.
d. Propagates over PIC waveguide 14.
e. Received by first port 22a of PIC 22.
f. Optically processed by PIC 22.
   is optically coupled to a second port 20b of WSC 20 via PIC waveguide 14.

The optically processed laser signal may be outputted from second port 22b of PIC 22 to post-PIC unit 15.

Once aligned—the position of the laser chip and the electrooptic chip may be fixed. For example—the laser chip can be bonded to the electrooptic chip, the electrooptic chip may be bonded to the laser chip—or one or both chips can be bonded to a third component.

The IML 30 is configured to fill air gaps between the laser chip and the electrooptic chip. The IML 30 may also be configured to mechanically bond the laser chip to the electrooptic chip.

The IML 30 may be configured to reduce reflection (related to radiation within the first wavelength range and the second wavelength range) which may evolve by an index mismatch due to air gaps between the laser chip and the electrooptic chip.

The IML 30 may be an Ultraviolet glue which is fabricated in a gel phase. In this case, the refractive index of the first waveguide may be fabricated from a core and of cladding layers that can be made of Oxide, Nitride, Si or any other dielectric material.

The low reflective coating layer may be designed to have a refractive index which matches the refractive index of the first waveguide 11, thereby reducing internal reflections magnitude between the laser chip 40 and the electrooptic chip 10.

The first waveguide 11 may include a plurality of waveguide segments of Nit and Ox, Oxynitride layers.

The first waveguide 11 may include tapers along the alignment waveguide of the Si layer edge.

The first waveguide 11 may include a combination of Nit and Ox, Oxynitride layers.

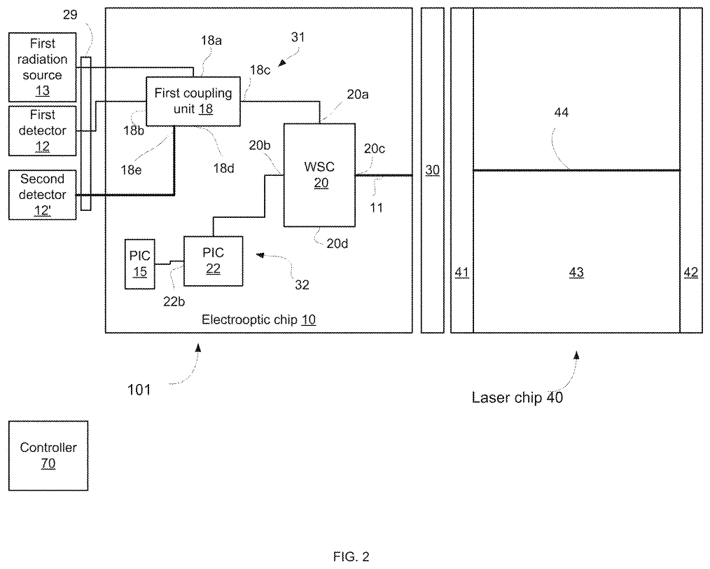

FIG. 2 illustrates a system 101 that includes laser chip 40, electrooptic chip 10, and Index Matching Layer (IML) 30.

A first detector 12, a second detector 12′, and a first radiation source 13 may also be included in system 101. The first detector 12, the first radiation source 13 and the second detector 12′ may be located outside the electrooptic chip 10 (as shown in FIG. 1) but at least one of them may belong to the electrooptic chip 10.

The first detector 12, the second detector 12′ and the first radiation source 13 may be optically coupled to the electrooptic chip in various manner—for example by a fiber array 29 that includes spaced apart fibers (illustrates as lines that pass through the rectangle denoted 29).

System 101 differ from system 100 by having a probe signal measurement circuit that includes a fifth port 18e of the first coupling unit and a second detector 12′. The additional port 16e provides a sample of the probe signal, and the second detector 12′ measures the sample.

The detection signals of the second detector may be sent to controller 70. Controller 70 may determine the different between the probe signal and the reflected probe signal.

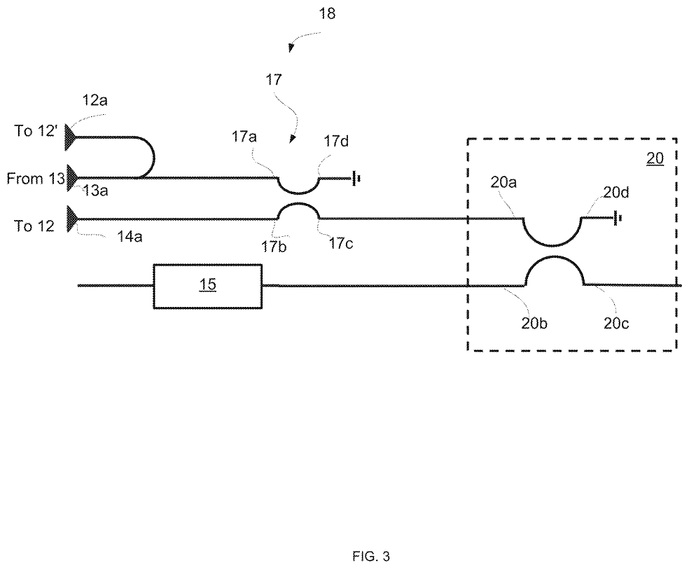

FIG. 3 illustrates an example of a part of the electrooptic chip 10—and especially of the first coupling unit 18 and the WSC 20.

First coupling unit 18 include first coupler 12a for providing reflected probe radiation to the first detector 12 (via second port 18b), second coupler 13a for receiving the probe radiation from the first radiation source 13 (via port 18a), third coupler 14a for providing a sample of the probe radiation (via port 18e) to second detector 12′, and fourth coupler 17.

There may be any type of couplers.

The first and second couplers may be grating couplers.

The fourth coupler 17 may be a 2×1 directional coupler that may be implemented by 2×2 directional coupler with a termination connected to fourth port 17d. The termination eliminates almost completely back reflections of the probe signal and the reflected probe signal.

First port 17a of fourth coupler 17 is optically coupled to an output of second coupler 12a.

Second port 17b of fourth coupler 17 is optically coupled to an output of first coupler 13a.

Third port 17c of fourth coupler 17 is optically coupled to a first port 20a of WSC 20.

The WSC 20 may be implemented in various manners—for example FIG. 3 illustrates the WSC as being implemented as a 2×2 directional coupler with a termination connected to fourth port 20d. The termination eliminates almost completely back reflections of the probe signal and the reflected probe signal.

The WSC can be replaced by SM optical 2×1 multiplexer or by an add-drop filter, configured to support a first internal optical path for radiation of the first wavelength range and a second internal path for radiation of the second wavelength range.

The WSC can include two parallel waveguides which are coupled by a ring resonator device so that at the first wavelength range, these waveguide are selectively coupled routing the signals of the first wavelength range to the coupler unit, and at the second wavelength range the signals are directed to the PIC.

The WSC device may include a ring resonator coupler which couples incoming light from the coupler unit at a resonant wavelength centered around the first wavelength, alignment waveguide at the Si part.

The WSC may include a ring resonator coupler which is composed out of two implanted n-type and p-type segments and an intrinsic segments, wherein n-type and p-type segments are externally contacted to Voltage source which is used to apply a voltage on the implanted n type and p-type side hence modify the refractive index of the ring resonator enabling a tuning of its resonant coupling wavelength.

The WSC may include a split ring resonators made of split ring resonator made of dielectric maleic or dielectric material which can be processed on the Si chip side and which can couple the incoming light from the coupler unit at a resonant wavelength centered around the first wavelength, waveguide alignment wave guide at the Si part.

The WSC may include WSC made of metallic split ring resonator.

The WSC may include made of a 1D, 2D or 3D photonic crystal structure made of rods holes in circular cylindrical or any arbitrary shape made of dielectric or metallic material which can processed on the Si chip and which can couple the incoming light from the coupler unit at a resonant wavelength centered around the first wavelength (21), waveguide alignment wave guide at the Si part.

It is noted that the WSC may provide selective routing of signals over more than two different wavelength ranges—and it has more than two WSC optical paths. This can be achieved by cascade of WSC devices, and/or by using multiple directional couplers.

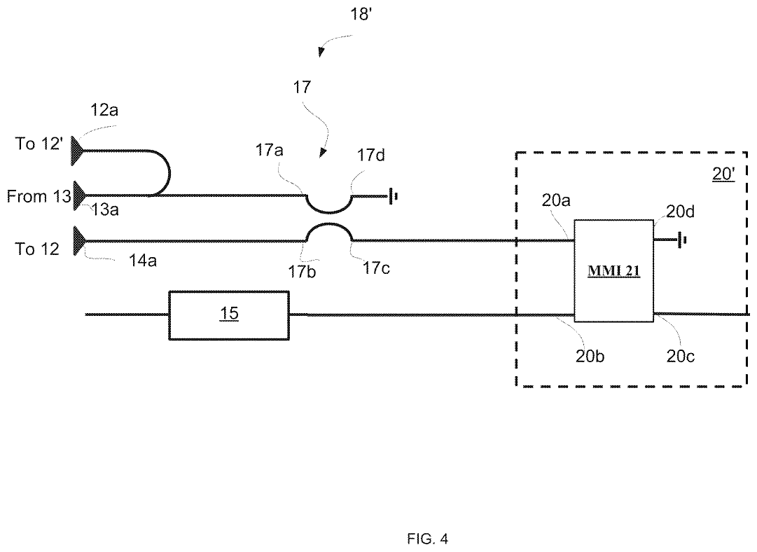

FIG. 4 illustrates an example of a part of the electrooptic chip 10—and especially of the first coupling unit 18 and the WSC 20′.

FIG. 4 illustrates WSC′ as including a multi-mode interference device (MMI) 21 instead of directional coupler (DC) illustrated in FIG. 3.

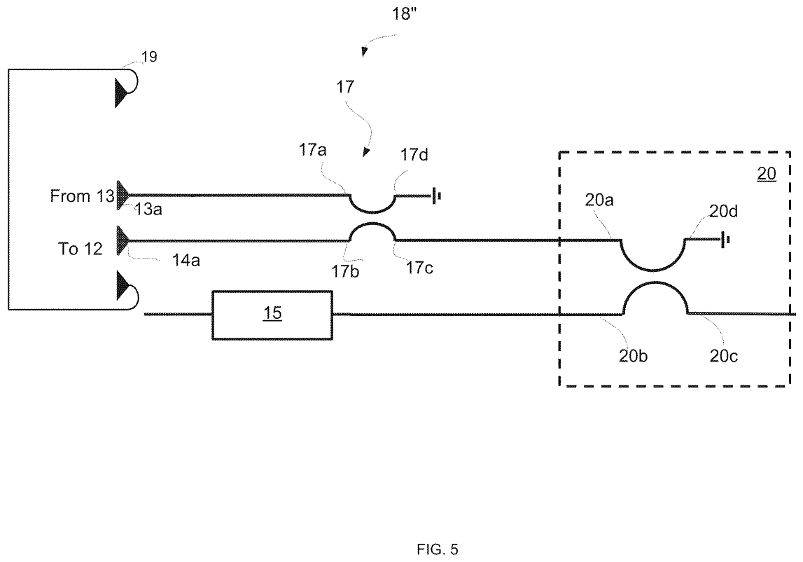

FIG. 5 illustrates an example of a part of the electrooptic chip 10—and especially of the first coupling unit 18 and the WSC 20′.

Instead of tapping the radiation from the first radiation source (as in FIG. 4)—a dedicated radiation source (for example other than first radiation source 13) is optically coupled (via loop 19) to the second detector 12′—thereby checking that the electrooptic chip 10 is aligned with the second detector 12′. This provides a feedback branch that does not use the radiation send to the laser chip.

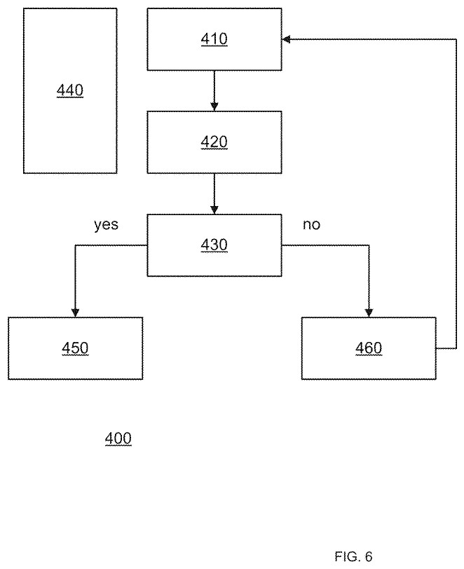

FIG. 6 illustrates an example of method 400.

Method 400 may be for aligning a laser chip with an electrooptic chip.

Method 400 may include one or more alignment iterations.

Each alignment iteration may start by step 410 of directing a probe signal from the electrooptic chip towards the laser chip.

Step 410 may be followed by step 420 of detecting a reflected probe signal by a first detector of the electrooptic chip, the reflected probe signal being reflected from the laser chip.

The probe signal and the reflected probe signal are within a first wavelength range.

The reflected probe signal passes through a first optical path of the electrooptic chip, the first optical path being configured to convey signals within the first wavelength range.

The first optical path differs from a second optical path of the electrooptic chip, the second optical path is configured to convey signals within a second wavelength range that differs from the first wavelength range.

The laser chip is configured to output a laser signal within the second wavelength range.

Steps 410 and 420 occur while maintaining a current spatial relationship between the laser chip and the electrooptic chip. This is illustrated by step 440 of maintaining a current spatial relationship between the laser chip and the electrooptic chip.

Step 420 may be followed by step 430 of determining, based on the reflected probe signal, whether the laser chip is aligned with the electrooptic chip.

If aligned—the step 430 may be followed by post-alignment step 450.

The post alignment step 450 may include, for example fixing the spatial relationship between the laser chip and the electrooptic chip.

If misaligned—step 430 may include changing (step 460) the current spatial relationship and jumping to step 410.

Step 460 may be executed in any manner—for example following a predefined set of spatial relationships, searching for a local or global alignment extremum point, and the like.

It should be noted that reaching a stop condition—for example—no alignment was obtained for at least a first plurality of alignment iterations—then an alignment failure may be declared.

Yet another stop condition is reaching a certain (while not perfect) alignment—after a second plurality of alignment iterations—then an alignment success may be declared.

Step 410 may include receiving the probe signal by a first wavelength selective coupler (WSC) port of a WSC of the electrooptic chip, directing the probe signal from the first WSC port to a second WSC port, through a first WSC optical path that is configured to convey signals within the first wavelength range, and outputting the probe signal from the second WSC port to a first waveguide.

Step 420 may include receiving the reflected probe signal by the second WSC port and from the first waveguide; and directing the reflected probe signal from the second WSC port to the first WSC port, through the first WSC optical path.

A third WSC port of the WSC is optically coupled to the second WSC port via a second WSC optical path that is configured to convey signals within the second wavelength range.

Method 400 may include step 460 of measuring a sample of the probe signal to provide a probe signal measurement. Step 430 may be responsive to the measurement—especially responsive to the difference of the probe signal (as indicated by the sample) and the reflected probe signal.

Method 400 may be executed while a laser of the laser chip is deactivated.

Steps 410 and 420 may be executed by an alignment unit of the electrooptic.

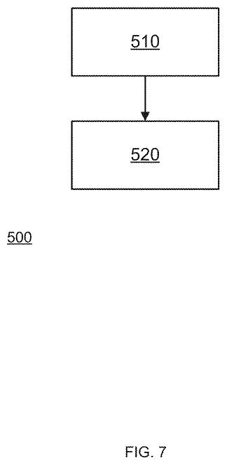

FIG. 7 illustrates an example of method 500.

Method 500 may be for operating a laser chip.

Method 500 may include step 510 of outputting a laser signal from the laser chip towards an electrooptic chip that is aligned with the laser chip.

Step 510 may be followed by step 520 of passing the laser signal through a second optical path of the electrooptic chip, the second optical path is configured to convey signals within a second wavelength range, wherein the laser signal is within the second wavelength range.

The alignment between the electrooptic chip and the laser chip may be obtained by executing any step of method 400.

The successful completion of method 400 may be a prerequisite to the execution of steps 510 and 520.

The Si chip/Electrooptic chip may be fabricated from Si on Insulator Wafers (SOI wafers). The SOI wafer may include the following layer stuck:
a. A Top silicon layer
b. An insulator layer fabricated from OX (labeled as BOX layer)
c. A bottom Silicon substrate.

PIC elements of the electro optical chip/Si chip, such as all waveguiding structures, couplers, grating couplers, WSC devices other couplers and all other devices may be fabricated on the SOI wafer Si top layer.

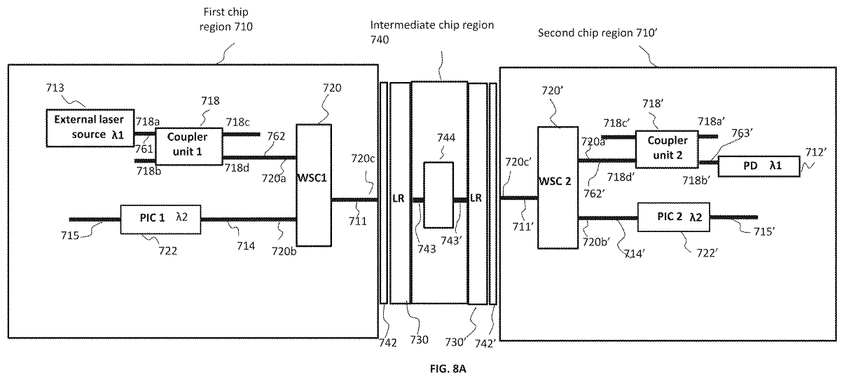

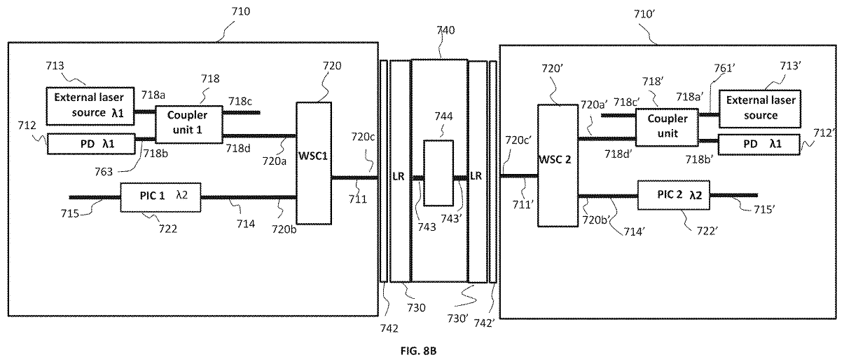

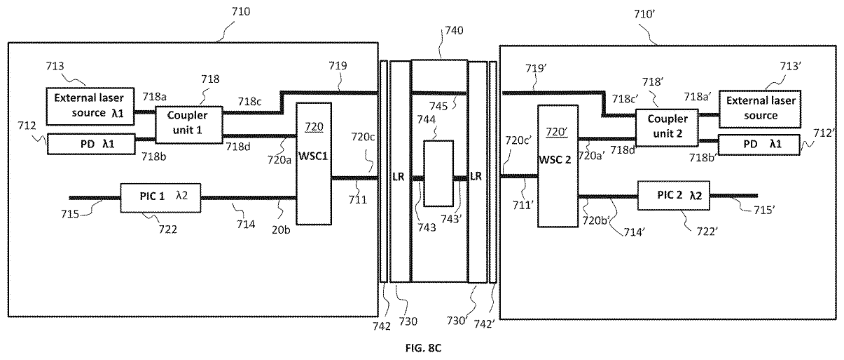

FIGS. 8A, 8B, and 8C illustrate examples of multiple chip regions that include first chip region 710, second chip region 710′ and intermediate chip region 740.

Ports of optical components and/or optical components may be optically coupled to each other using waveguides. For simplicity of explanation only some of the waveguides are associated with reference numbers.

In FIG. 8A the first chip region 710 includes external laser source 713, first coupler unit 718 (having ports 718a, 718b, 718c and 718d), first WSC (WSC1) 720 (having ports 720a, 720b and 720c), and first PIC (PIC 1) 722, as well as waveguides 711, 714 and 715.

Port 718a is optically coupled (via waveguide 761) to an output of the external laser source 713. Port 718d is optically coupled (via waveguide 762) to port 720a. Port 720c is optically coupled to waveguide 711. Ports 720b is optically coupled to waveguide 714 and to one port of PIC-1 722. Another port of PIC-1 722 is optically coupled to waveguide 715.

In FIGS. 8B and 8C the first chip region also includes a second detector (PD) 712 that is optically coupled (via waveguide 763) to port 718b.

In FIG. 8A the second chip region 710′ includes first detector (PD) 712′, second coupler unit 718′ (having ports 718a′, 718b′, 718c′ and 718d′), second WSC (WSC2) 720′ (having ports 720a′, 720b′ and 720c′), and second PIC (PIC 2) 722′, as well as waveguides 711′, 714′ and 715′.

Port 718b′ is optically coupled (via waveguide 763′) to an input of first detector 712′. Port 718d′ is optically coupled (via waveguide 762′) to port 720a′. Port 720c′ is optically coupled to waveguide 711′. Ports 720b′ is optically coupled to waveguide 714′ and to one port of PIC-2 722′. Another port of PIC-2 722′ is optically coupled to waveguide 715′.

In FIG. 8B the second chip region 710′ also includes another external laser source 713′ that is optically coupled (via waveguide 763′) to port 718a′.

In FIGS. 8A, 8B and 8C the intermediate chip region 740 includes an active electrooptical component 744 such as a Silicon Optical Amplifier (SOA), and waveguides 743 and 743′ that are optically coupled to the active electrooptical component. An at least partially transparent path (to the first wavelength band and to the second wavelength band) passes through IML layer 742, LR layer waveguide 730, waveguide 743, the active electrooptical component, waveguide 743′, LR layer 730′ and then IML layer 742. It should be noted that instead of listing the components according to their order—any out of order reference to the path may be provided (for brevity of explanation).

In FIG. 8C there is another at least partially transparent path that passes through an auxiliary waveguide 745. The other at least partially transparent path also passes through the IML layers 742 and 742′ and through LR layers 730 and 730′. In this case the alignment may be executed without passing through the active electrooptical component.

When the multiple chip regions are aligned—one end of the auxiliary waveguide 745 is aligned with waveguide 719 that is optically coupled to port 718c, another end of the auxiliary waveguide 745 is aligned with waveguide 719′ that is optically coupled to port 718c′.

In FIG. 8A an alignment iteration may include transmitting by external laser source 713 a first optical probe signal of first wavelength band (that includes first wavelength λ1) to port 718b, through coupler unit-1 718, from port 718d to port 720a, through WSC1 720, from port 720c, through waveguide 711 and towards LR layer 730, IML layer 742 and to intermediate chip region 740.

If the multiple chip regions are aligned, the first optical probe signal passes through waveguides 743 and 743′ and active electrooptical component 744, through IML layer 742′, through LR layer 730′, through waveguide 711′, to port 720c′, through WSC-2 720′, from port 720a′, through coupler unit-2 718′, from port 718b′ to first detector PD 712′.

If the multiple chip regions are not aligned the first detector PD 712′ may not receive any significant signal.

After the multiple chip regions are aligned and bonded and after the active electrooptical component 744 can be activated (may be required to form conductive paths for activating the active electrooptical component)—then PIC-1 722 may provide, during a transmission iteration, a transmitted optical signal of the second wavelength band (PIC-1 722 may generate the transmitted optical signal or may receive the transmitted optical signal via waveguide 715). The transmitted optical signal may propagate over waveguide 714, to port 720b, through WCS-1 720, from port 720c, through waveguide 711 and towards LR layer 730. IML layer 742 and to intermediate chip region 740, through the intermediate chip region (through waveguides 743, especially be received by active electrooptical component 744 and be optically processed—for example amplified), through IML layer 742′, through LR layer 730′, through waveguide 711′, to port 720c′, through WSC-2 720′, from port 720b′, to PIC-2 722′, through waveguide 715′ and outside the second chip region.

The reverse direction path may be provided from PIC-2 722′ to PIC-1 722.

FIG. 8B illustrates another path that can be used during an alignment iteration. The path includes conveying a second optical probe signal of the first waveband from external laser source 713′ to port 718a′, through second coupler unit 718′, from port 718d′, to port 720a′, through WSC-2 720′, from port 720c′, through waveguide 711′, through LR layer 730′ and IML layer 742′. If the multiple chip regions are aligned, the second optical probe signal passe through waveguides 743 and active electrooptical component 744, reach waveguide 711, to port 720c, through WSC-1 720, from port 720a, to port 718d, through first coupler unit 718, from port 718b to second detector (PD) 712.

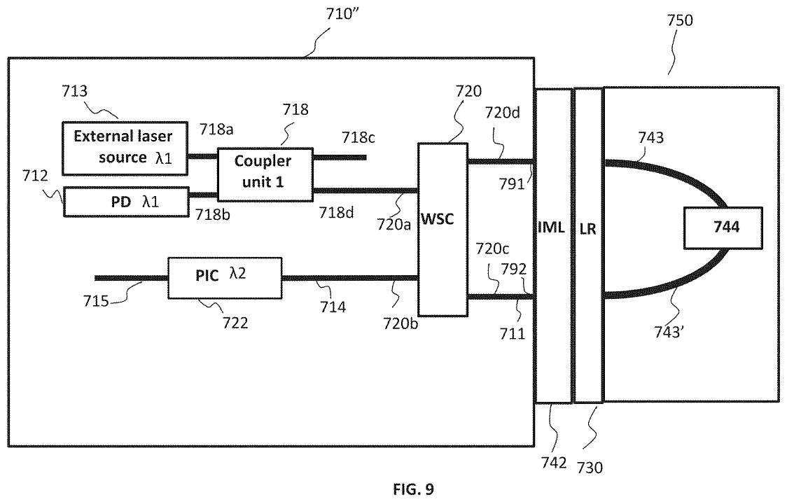

FIG. 9 illustrates a first chip region 710″ and another chip region 750.

The first chip region 710″ of FIG. 9 may include external laser source 713, first coupler unit 718 (having ports 718a, 718b, 718c and 718d), first WSC (WSC1) 720 (having ports 720a, 720b, 720c and 720d), and first PIC (PIC 1) 722, second detector (PD) 712, first port 791, second port 792, as well as waveguides 711, 714 and 715.

Port 718a is optically coupled to an output of the external laser source 713. Port 718d is optically coupled to port 720a. Port 720c is optically coupled to waveguide 711 that terminates in second port 792. Port 720d is optically coupled (via a waveguide) to first port 791. Port 720b is optically coupled to waveguide 714 and to one port of PIC-1 722. Another port of PIC-1 722 is optically coupled to waveguide 715.

During an alignment iteration the external laser source 713 transmits a first optical probe signal of first wavelength band (that includes first wavelength λ1) to port 718a, through coupler unit-1 718, from port 718d to port 720a, through WSC1 720, from port 720d, through waveguide 711 and towards IML layer 742, LR layer 730 and to other chip region 750.

If the multiple chip regions are aligned, the first optical probe signal passes through waveguide 743′, through active electrooptical component 744, through LR layer 730, through IML layer 742, through LR layer 730, through a waveguide to port 720d, through WSC-1 720, from port 720a, to port 718d, through coupler unit-1 718, from port 718b to second detector PD 712.

If the multiple chip regions are not aligned the first detector PD 712 may not receive any significant signal.

After the multiple chip regions are aligned and bonded and after the active electrooptical component 744 can be activated (may require to form conductive paths for activating the active electrooptical component)—then PIC-1 722 may provide, during a transmission iteration, a transmitted optical signal of the second wavelength band (PIC-1 722 may generate the transmitted optical signal or may receive the transmitted optical signal via waveguide 715). The transmitted optical signal may propagate over waveguide 714, to port 720b, through WCS-1 720, from port 720c, through waveguide 711 and towards LR layer 730, IML layer 742 and to other chip region 750, through the other chip region (through waveguide 743′, especially be received by active electrooptical component 744 and be optically processed—for example amplified, and through waveguide 743), through LR layer 730, through IML layer 742, through a waveguide to port 720d, through WSC-1 720, from port 720b back to PIC-1 722, through waveguide 715′ and outside the second chip region. Another PCI may receive the transmitted optical signal after being optically processed by the active electrooptical component 744.

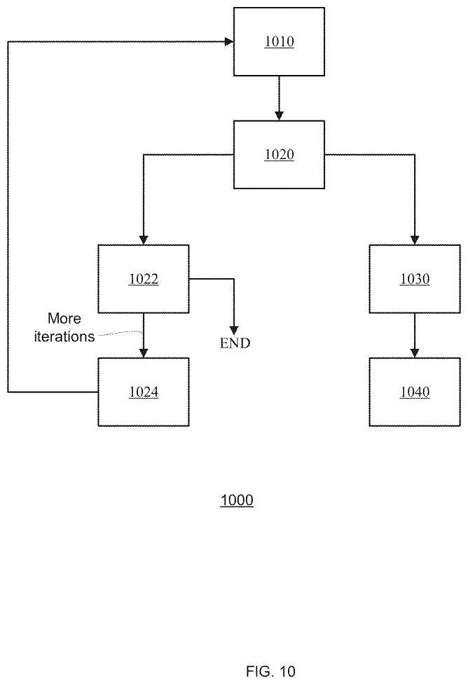

FIG. 10 illustrates method 1000 for optically aligning multiple chip regions.

Method 1000 may include multiple alignment iteration. The method may include one or more alignment iterations. The alignment iterations may stop when alignment is reached, or when the alignment is deemed to fail.

Method 1000 may start by step 1010 of directing, during an alignment iteration, a first optical probe signal of a first wavelength band, from a first chip region towards an intermediate chip region. The multiple chip regions may include the first chip region, the intermediate chip region, and a second chip region.

The intermediate chip region may include an intermediate optical path, that is at least partially transparent to the first wavelength band and to a second wavelength band. The second wavelength band does not overlap the first wavelength band. The active electrooptical component is maintained idle during the alignment iteration.

When the multiple chip regions are aligned the intermediate optical path optically couples the multiple chip regions.

Step 1010 may include at least one of the following:
a. Receiving, during the alignment iteration, the first optical probe signal by a wavelength selective coupler (WCS) first port (for example port 720a of FIG. 8A).
b. Directing the first optical probe signal from the WSC first port to a WSC second port (for example port 720c of FIG. 8A), through a WSC first optical path that is configured to convey signals within the first wavelength range.
c. When the multiple chips are aligned—outputting the first optical probe signal from the WSC second port to the intermediate optical path. The WSC first port, the WSC second port and a WSC third port (for example port 720b of FIG. 8A) belong to a first WSC of the first chip region.
d. When the multiple chips are aligned—receiving the first optical probe signal by a WSC fourth port (for example port 720c′ of FIG. 8A).
e. When the multiple chips are aligned—directing the first optical probe signal from the WSC fourth port to a WSC fifth port (for example port 720a′ of FIG. 8A), through a WSC third optical path that is configured to convey signals within the first wavelength range.
f. When the multiple chips are aligned—outputting the first optical probe signal from the WSC fifth port to the detector of the second chip region. The WSC fourth port, the WSC fifth port and a WSC sixth port (for example port 720b′ of FIG. 8A) belong to a second WSC of the second chip region.

Step 1010 may be followed by step 1020 of evaluating one or more signals generated by a detector of the second chip region during the alignment iteration to determine whether the multiple chip regions are aligned.

If it is determined that the multiple chips regions are not aligned—step 1020 may be followed by step 1022 of determining whether to perform another alignment iteration.

Step 1022 may be followed by ending the method (“END”) when determining not to perform another alignment iteration.

Step 1022 may be followed by step 1024 of changing the spatial relationship between the multiple chips and jumping to step 1010—when determining to perform the other alignment iteration.

If it is determined that the multiple chips regions are aligned—step 1020 may be followed by step 1030 of maintaining a spatial relationship between the multiple chip regions.

Step 1030 may include attaching—for example—bonding the multiple chip regions.

Step 1030 may be followed by step 1040 of operating the multiple chip regions.

Step 1040 may be preceded by enabling the active electrooptical component to be activated—for example forming conductive paths to activate the active electrooptical component.

Step 1040 may include at least one of:
a. Activating the active electrooptical component.
b. Directing, during a transmission iteration, a transmitted optical signal of the second wavelength band towards the intermediate chip region, following the bonding.
c. Receiving, during the transmission iteration, the transmitted optical signal by a WCS third port.
d. Directing the transmitted optical signal from the WSC third port to the WSC second port, through a WSC second optical path that is configured to convey signals within the second wavelength range.
e. Outputting the transmitted optical signal from the WSC second port to the intermediate optical path.
f. Receiving the transmitted optical signal by the WSC fourth port. Directing the transmitted optical signal from the WSC fourth port to the WSC sixth port, through a WSC fourth optical path that is configured to convey signals within the second wavelength range. outputting the transmitted optical signal from the WSC sixth port.

The intermediate optical path may pass through the active electrooptical component.

The intermediate optical path may not pass through the active electrooptical component—for example may pass through an auxiliary path.

The active electrooptical component may be a semiconductor optical amplifier (SOA)—or may differ from the SOA.

The first chip region and the second chip region may belong to a single integrated circuit.

The intermediate optical path may include one or more waveguides and anti-reflective elements.

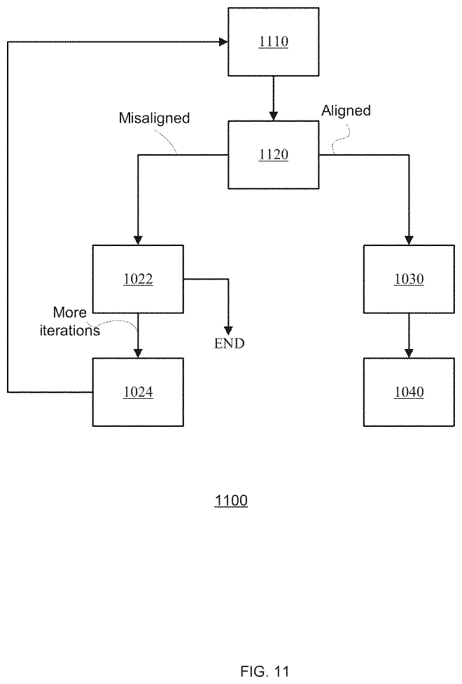

FIG. 11 illustrates method 1100 for optically aligning multiple chip regions.

Method 1100 may start by step 1110 of directing, during an alignment iteration, a first optical probe signal of a first wavelength band, from a first port of a first chip region towards another chip region. The multiple chip regions may include the first chip region and the other chip region.

The second chip region may include an intermediate optical path that is at least partially transparent to the first wavelength band and to a second wavelength band, the second wavelength band does not overlap the first wavelength band.

The intermediate optical path may pass or may not pass through an active electrooptical component of the intermediate chip region. The active electrooptical component is idle during the alignment iteration.

When the multiple chip regions are aligned the intermediate optical path optically couples the first port (for example first port 791 of FIG. 9) of the first chip region to a second port (for example second port 792 of FIG. 9) of the first chip region.

Step 1110 may be followed by step 1120 of evaluating one or more signals generated by a detector of the first chip region during the alignment iteration to determine whether the multiple chip regions are aligned.

Step 1120 may be followed by step 1130 of maintaining a spatial relationship between the multiple chip regions when it is determined that the multiple chip regions are aligned.

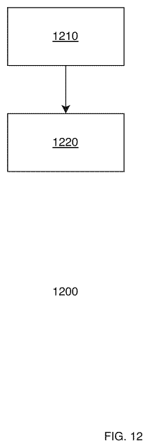

FIG. 12 illustrates an example of a method 1200 for operating multiple chip regions.

According to an embodiment, method 1200 includes step 1210 of aligning the multiple chip regions using optical probe signals of a first wavelength band that are sent to an alignment path that is formed within the multiple chip regions and ends with a detector of the first chip region, wherein an attenuation value of the alignment path is indicative of an alignment between the multiple chip regions.

According to an embodiment, the multiple chip regions include the first chip region, a second chip region and an intermediate chip region located between the first chip region and the second chip region.

According to an embodiment, the intermediate chip is at least partially transparent to a second wavelength band and to the first frequency wavelength band. The second chip region comprises an active electrooptical component that is idle during the aligning step.

According to an embodiment, spaced apart ports of the second chip region are optically coupled to the active electrooptical component.

According to an embodiment, step 1210 is followed by step 1220 of receiving from a second wavelength source that is external to the multiple chip regions, a transmitted optical signal of the second wavelength band, the second wavelength band does not overlap the first wavelength band.

According to an embodiment, step 1220 is followed by:
a. Conveying the transmitted optical signal, through an ingress part of a transmission path formed within the multiple chip regions, to the active electrooptical component.
b. Electrooptically processing the transmitted optical signal by the active electrooptical component to provide a processed transmitted optical signal.
c. Outputting, through an egress part of the transmission path, the processed transmitted optical signal from the multiple chip regions.

According to an embodiment an ingress part of the alignment path and the ingress part of the transmission path share at least a first combiner, a wavelength selective coupler (WSC), and the spaced apart ports.

According to an embodiment, the ingress part of the alignment path and the ingress part of the transmission path share further share a circulator that couples a third WSC port of the WSC and each one of the spaced apart ports.

According to an embodiment, the aligning comprises conveying the probe signals from the third WSC port to a first port of the spaced apart ports and conveying the probe signals from the third WSC port to the first WSC port.

According to an embodiment, the alignment uses reflected signals from the second chip region—the reflected signals are reflected from a sidewall of the second chip region that interfaces the intermediate chip region.

Additionally or alternatively—the alignment uses transmissive signals that pass through the second chip region.

According to an embodiment, method 1200 further includes conveying the transmitted optical signal from the first WSC port to the first port of the spaced apart port, and conveying the processed transmitted signal from the third WSC port to a second WSC port of the WSC.

According to an embodiment, method 1200 includes outputting the processed second wavelength band optical signal to an ingress port of a transmission path formed within other multiple chip regions.

According to an embodiment, the aligning of the multiple chip regions using optical probe signals comprises multiple alignment iterations, wherein each alignment iteration comprises directing one of the optical probe signals towards the alignment path, wherein while the multiple chip regions are misaligned the one of the optical probe signals fails to reach a detector of a first chip region.

According to an embodiment, method 1200 further includes determining whether to perform another alignment iteration when it is determined that the multiple chip regions are misaligned; and changing the spatial relationship between the multiple chips and performing the other alignment iteration when it is determined to perform the other alignment iteration.

According to an embodiment, method 1200 includes maintaining a spatial relationship between the multiple chip regions when it is determined that the multiple chip regions are aligned.

According to an embodiment, the maintaining of the spatial relationship includes bonding the multiple chip regions to each other.

According to an embodiment, the alignment path passes through the active electrooptical component.

According to an embodiment, the alignment path does not pass through the active electrooptical component. There may be provided an auxiliary path that bypasses the active electrooptical component—see, for example, the auxiliary path of FIG. 8C that includes waveguides 719, 745 and 719′.

According to an embodiment, the active electrooptical component is a semiconductor optical amplifier (SOA). Any other optical element that optically processes the optical signal may be provided—for example filter, polarization processor, amplitude processor and the like.

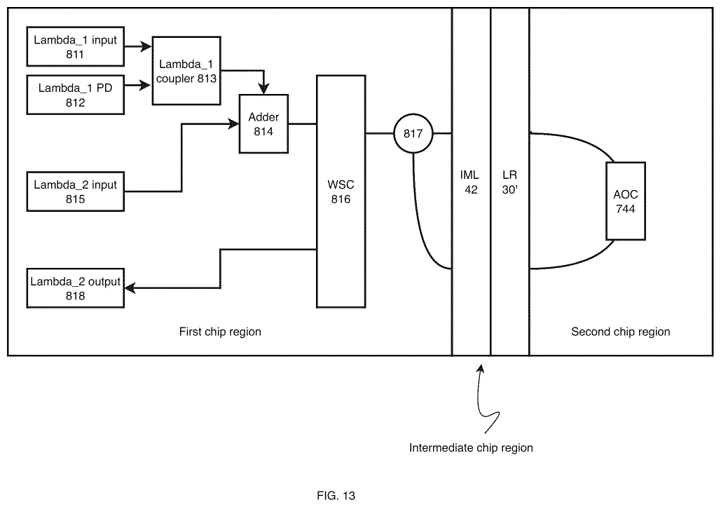

FIG. 13 illustrates an example of multiple chip regions. The multiple chip regions include (i) first chip region that includes a first wavelength band input 811, a first wavelength band detector (PD) 812, a first wavelength band coupler 813, a first combiner (adder 814), a second wavelength band input (815), second wavelength band output (818), and wavelength selective coupler (WSC) 816 that includes a first WSC port, a second WCS port and a third SCS port; (ii) an intermediate chip region (illustrated as including IML 42 and LR 30′) that is at least partially transparent to a second wavelength band and to the first frequency wavelength band, and (iii) a second chip region that includes spaced apart ports and an active electrooptical component (744) and waveguides located between the spaced apart ports and the active electrooptic component.

According to an embodiment, the multiple chips regions form an alignment path and a transmission path, each path optically couples the multiple chip regions to each other, wherein an attenuation value of the alignment path is indicative of an alignment between the multiple chip regions.

According to an embodiment, an ingress part of the alignment path includes the first wavelength band input, the first wavelength band input, the first wavelength band coupler, the first combiner, the first WSC port, the third WSC port, a first WSC path between the first WSC port and the third WSC port, the intermediate chip region, a first port of the spaced apart ports.

According to an embodiment, an egress part of the alignment path includes a second port of the spaced apart ports, the intermediate chip region, the third WSC port, the first WSC path, the first WSC port, the first combiner, the first wavelength band coupler, and the first detector.

According to an embodiment, an ingress part of the transmission path includes a second wavelength band input, the first combiner, the first WSC port, the third WSC port, the first WSC path, the intermediate chip region, and the first port of the spaced apart ports; wherein an egress part of the transmission path includes the second port of the spaced apart ports, the intermediate chip region, the third WSC port, the second WSC path between the second WSC port and the third WSC port, and the second wavelength band output.

According to an embodiment, the transmission path and the alignment path share a circulator that optically couples the third WSC port and each one of the spaced apart ports.

According to an embodiment, the multiple chip regions participate in the execution of method 1200.

According to an embodiment, the first chip region is further adapted to convey the transmitted optical signal from the first WSC port to the first port of the spaced apart port, and to convey the processed transmitted signal from the third WSC port to a second WSC port of the WSC.

According to an embodiment, the first chip region is further adapted to output the processed second wavelength band optical signal to an ingress port of a transmission path formed within other multiple chip regions.

According to an embodiment, the alignment path passes through the active electrooptical component.

According to an embodiment, the alignment path does not pass through the active electrooptical component.

According to an embodiment, wherein the active electrooptical component is a semiconductor optical amplifier (SOA).

According to an embodiment, having the second wavelength input 815 allows to receive second wavelength band signals from a source outside the multiple chip regions. Having the second wavelength input and the second wavelength output allows to distribute second wavelength band signals between different chips—and/or between different groups of multiple chip regions.

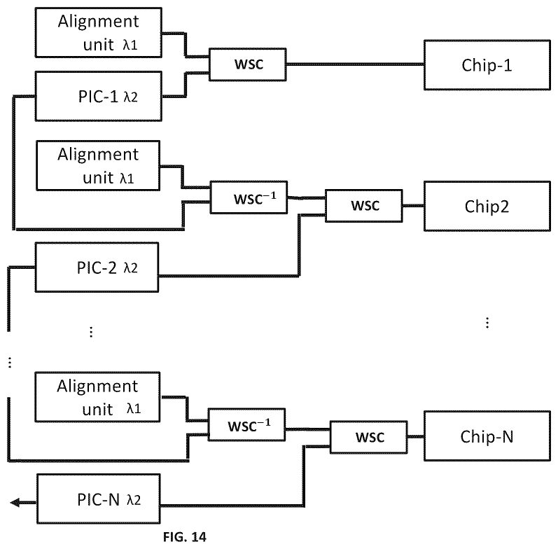

FIG. 14 illustrate a second wavelength band source (for example chip 1 of FIG. 14) that provides a second wavelength band signal to another electrooptic chip (or another electrooptic chip region or to multiple chip regions), and the like—see for example electrooptical chips or first chip regions in optical communication with second till N'th chips.

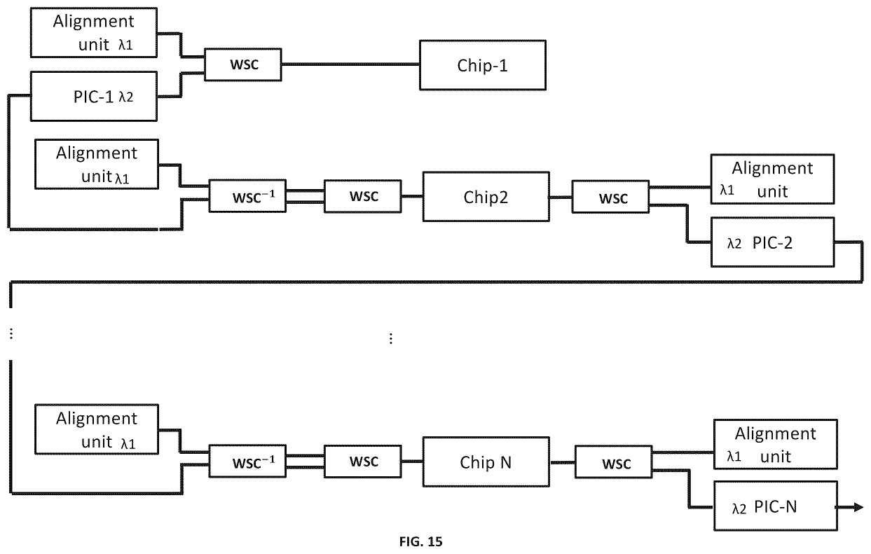

According to an embodiment, the second wavelength band signal may be generated by a laser chip (denoted 40 in FIG. 1) and pass through an electrooptic chip (denoted 10 in FIG. 1 or 101 in FIG. 2) and provided to one or more sets of chips (such as any of the sets of chips including chips 710, 740, 710′ of FIGS. 8A, 8B, 8C and 9) and/or to chip or chip region 750 of FIG. 9. See, for example FIG. 15 illustrating parts of a first chip (alignment unit, adder—denoted WSC⁻¹ and WSC, and chip 2 (till chip N) that also includes WSC alignment unit and second wavelength band output.

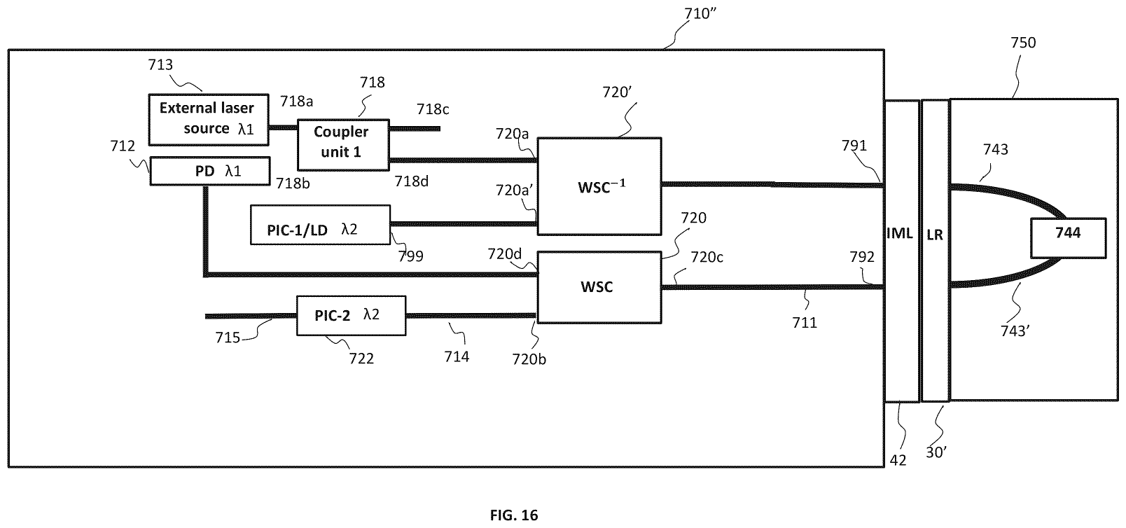

FIG. 16 illustrates multiple chip regions in which:
a. There is no circulator.
b. The WSC (720) is not a part of any ingress path—and is shared by the egress part of the transmission path and of the alignment path.
c. The first wavelength detector 799 receives the probe signal from a first WCS port via waveguide 720d.
d. The output of the adder is optically coupled (especially when alignment is obtained) to a first port of the spaced apart ports of the second chip region (the adder is denoted WSC-1 720′).
e. A third WCS port is optically coupled (especially when alignment is obtained) to a second port of the spaced apart ports of the second chip region.

In FIG. 16 the alignment process may use reflection from the second chip region (especially location in front of the waveguide) and may use transmission (via WCS and waveguide).

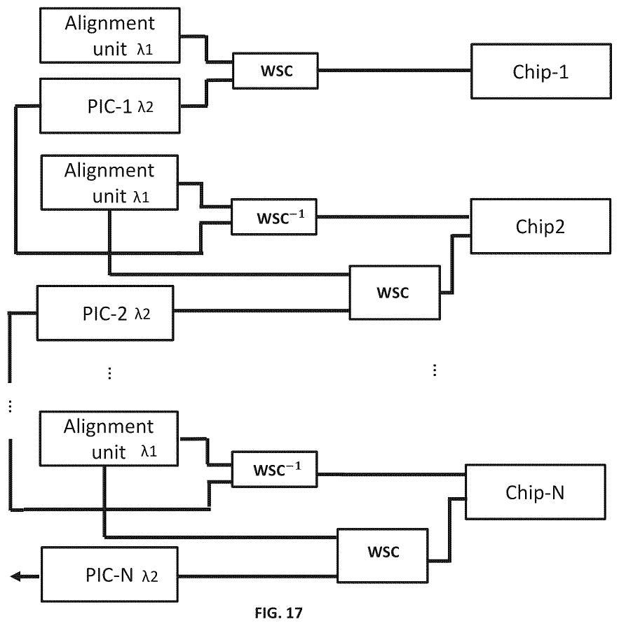

FIG. 17 illustrates an example of cascading chips and/or chip regions—at least some having first chip regions of a configuration illustrated in FIG. 16.

According to an embodiment, there is provided a method for operating multiple chip regions, the method includes (i) aligning the multiple chip regions using optical probe signals of a first wavelength band that are sent to an alignment path that is formed within the multiple chip regions and ends with a detector of the first chip region, wherein an attenuation value of the alignment path is indicative of an alignment between the multiple chip regions; wherein the multiple chip regions includes the first chip region, a second chip region and an intermediate chip region located between the first chip region and the second chip region; wherein the intermediate chip is at least partially transparent to a second wavelength band and to the first frequency wavelength band; wherein the second chip region includes an active electrooptical component that is idle during the aligning step; wherein spaced apart ports of the second chip region are optically coupled to the active electrooptical component; (ii) receiving, following the aligning of the multiple chip regions, from a second wavelength source that is external to the multiple chip regions, a transmitted optical signal of the second wavelength band, the second wavelength band does not overlap the first wavelength band; (iii) conveying the transmitted optical signal, through an ingress part of a transmission path formed within the multiple chip regions, to the active electrooptical component; (iv) electrooptically processing the transmitted optical signal by the active electrooptical component to provide a processed transmitted optical signal; and (v) outputting, through an egress part of the transmission path, the processed transmitted optical signal from the multiple chip regions. An ingress part of the alignment path and the ingress part of the transmission path share at least a first combiner, and the spaced apart ports.

According to an embodiment, the egress part of the alignment path and the egress part of the transmission path further share a wavelength selective coupler (WSC).

According to an embodiment, the ingress part of the alignment path and the ingress part of the transmission path further share a wavelength selective coupler (WSC).

According to an embodiment, the ingress part of the alignment path and the ingress part of the transmission path share further share a circulator that couples a third WSC port of the WSC and each one of the spaced apart ports.

According to an embodiment, the aligning includes conveying the probe signals from the third WSC port to a first port of the spaced apart ports and conveying the probe signals from the third port to a first WSC port of the WSC.

The method According to an embodiment, the method includes conveying the transmitted optical signal from the first WSC port to the first port of the spaced apart port, and conveying the processed transmitted signal from the third WSC port to a second WSC port of the WSC.

According to an embodiment, the method includes outputting the processed second wavelength band optical signal to an ingress port of a transmission path formed within other multiple chip regions.

According to an embodiment, the aligning of the multiple chip regions using optical probe signals includes multiple alignment iterations, wherein each alignment iteration includes directing one of the optical probe signals towards the alignment path, wherein while the multiple chip regions are misaligned the one of the optical probe signals fails to reach a detector of a first chip region.

According to an embodiment, the method includes determining whether to perform another alignment iteration when it is determined that the multiple chip regions are misaligned; and changing the spatial relationship between the multiple chips and performing the other alignment iteration when it is determined to perform the other alignment iteration.

According to an embodiment, includes maintaining a spatial relationship between the multiple chip regions when it is determined that the multiple chip regions are aligned.

According to an embodiment, the maintaining of the spatial relationship includes bonding the multiple chip regions to each other.

According to an embodiment, the alignment path passes through the active electrooptical component.

According to an embodiment, the alignment path does not pass through the active electrooptical component.

According to an embodiment, the active electrooptical component is a semiconductor optical amplifier (SOA).

According to an embodiment, there are provided multiple chip regions, the multiple chip regions includes: (i) a first chip region that includes a first wavelength band input, a first wavelength band detector, a first wavelength band coupler, a first combiner, a second wavelength band input, second wavelength band output, and wavelength selective coupler (WSC) includes a first WSC port, a second WSC port and a third WSC port; (ii) an intermediate chip region that is at least partially transparent to a second wavelength band and to the first frequency wavelength band; and (iii) a second chip region that includes spaced apart ports and an active electrooptical component. The multiple chips regions form an alignment path and a transmission path, each path optically couples the multiple chip regions to each other, wherein an attenuation value of the alignment path is indicative of an alignment between the multiple chip regions. An ingress part of the alignment path includes the first wavelength band input, the first wavelength band input, the first wavelength band coupler, the first combiner, the first WSC port, the third WSC port, a first WSC path between the first WSC port and the third WSC port, the intermediate chip region, a first port of the spaced apart ports. An egress part of the alignment path includes a second port of the spaced apart ports, the intermediate chip region, the third WSC port, the first WSC path, the first WSC port, the first combiner, the first wavelength band coupler, and the first detector. An ingress part of the transmission path includes a second wavelength band input, the first combiner, the first WSC port, the third WSC port, the first WSC path, the intermediate chip region, and the first port of the spaced apart ports. An egress part of the transmission path includes the second port of the spaced apart ports, the intermediate chip region, the third WSC port, the second WSC path between the second WSC port and the third WSC port, and the second wavelength band output.

According to an embodiment, the egress part of the alignment path and the egress part of the transmission path further share a wavelength selective coupler (WSC).

According to an embodiment, the ingress part of the alignment path and the ingress part of the transmission path further share a wavelength selective coupler (WSC).

According to an embodiment, the ingress part of the alignment path and the ingress part of the transmission path share further share a circulator that couples a third WSC port of the WSC and each one of the spaced apart ports.

According to an embodiment, the transmission path and the alignment path share a circulator that optically couples the third WSC port and each one of the spaced apart ports.

According to an embodiment, the first chip region is further adapted to output the processed second wavelength band optical signal to an ingress port of a transmission path formed within other multiple chip regions.

In the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope and spirit of the invention as claimed.

Any reference to comprising or including should be applied mutatis mutandis to consisting and/or to “consisting essentially of”.

In the foregoing specification, the invention has been described with reference to specific examples of embodiments of the invention. It will, however, be evident that various modifications and changes may be made therein without departing from the broader spirit and scope of the invention as set forth in the appended claims.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures may be implemented which achieve the same functionality.

Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

It is appreciated that various features of the embodiments of the disclosure which are, for clarity, described in the contexts of separate embodiments may also be provided in combination in a single embodiment. Conversely, various features of the embodiments of the disclosure which are, for brevity, described in the context of a single embodiment may also be provided separately or in any suitable sub-combination.

It will be appreciated by persons skilled in the art that the embodiments of the disclosure are not limited by what has been particularly shown and described hereinabove. Rather the scope of the embodiments of the disclosure is defined by the appended claims and equivalents thereof.

We claim:

1. A method for operating multiple chip regions, the method comprises:
aligning the multiple chip regions using optical probe signals of a first wavelength band that are sent to an alignment path that is formed within the multiple chip regions and ends with a detector of the first chip region, wherein an attenuation value of the alignment path is indicative of an alignment between the multiple chip regions;
wherein the multiple chip regions comprise the first chip region, a second chip region and an intermediate chip region located between the first chip region and the second chip region;
wherein the intermediate chip is at least partially transparent to a second wavelength band and to the first frequency wavelength band;
wherein the second chip region comprises an active electrooptical component that is idle during the aligning step;
wherein spaced apart ports of the second chip region are optically coupled to the active electrooptical component;
receiving, following the aligning of the multiple chip regions, from a second wavelength source that is external to the multiple chip regions, a transmitted optical signal of the second wavelength band, the second wavelength band does not overlap the first wavelength band;
conveying the transmitted optical signal, through an ingress part of a transmission path formed within the multiple chip regions, to the active electrooptical component;
electrooptically processing the transmitted optical signal by the active electrooptical component to provide a processed transmitted optical signal; and
outputting, through an egress part of the transmission path, the processed transmitted optical signal from the multiple chip regions; and
wherein an ingress part of the alignment path and the ingress part of the transmission path share at least a first combiner, and the spaced apart ports.

2. The method according to claim 1, wherein the egress part of the alignment path and the egress part of the transmission path further share a wavelength selective coupler (WSC).

3. The method according to claim 1, wherein the ingress part of the alignment path and the ingress part of the transmission path further share a wavelength selective coupler (WSC).

4. The method according to claim 3, wherein the ingress part of the alignment path and the ingress part of the transmission path share further share a circulator that couples a third WSC port of the WSC and each one of the spaced apart ports.

5. The method according to claim 4, wherein the aligning comprises conveying the probe signals from the third WSC port to a first port of the spaced apart ports and conveying the probe signals from the third port to a first WSC port of the WSC.

6. The method according to claim 5, further comprising conveying the transmitted optical signal from the first WSC port to the first port of the spaced apart port, and conveying the processed transmitted signal from the third WSC port to a second WSC port of the WSC.

7. The method according to claim 1, further comprising outputting the processed second wavelength band optical signal to an ingress port of a transmission path formed within other multiple chip regions.

8. The method according to claim 1, wherein the aligning of the multiple chip regions using optical probe signals comprises multiple alignment iterations, wherein each alignment iteration comprises directing one of the optical probe signals towards the alignment path, wherein while the multiple chip regions are misaligned the one of the optical probe signals fails to reach a detector of a first chip region.

9. The method according to claim 8, further comprising determining whether to perform another alignment iteration when it is determined that the multiple chip regions are misaligned; and changing the spatial relationship between the multiple chips and performing the other alignment iteration when it is determined to perform the other alignment iteration.

10. The method according to claim 1, comprising maintaining a spatial relationship between the multiple chip regions when it is determined that the multiple chip regions are aligned.

11. The method according to claim 10, wherein the maintaining of the spatial relationship comprises bonding the multiple chip regions to each other.

12. The method according to claim 1, wherein the alignment path passes through the active electrooptical component.

13. The method according to claim 1, wherein the alignment path does not pass through the active electrooptical component.

14. The method according to claim 1, wherein the active electrooptical component is a semiconductor optical amplifier (SOA).

15. Multiple chip regions, the multiple chip regions comprise:
a first chip region that comprises a first wavelength band input, a first wavelength band detector, a first wavelength band coupler, a first combiner, a second wavelength band input, second wavelength band output, and wavelength selective coupler (WSC) comprising a first WSC port, a second WSC port and a third WSC port;
an intermediate chip region that is at least partially transparent to a second wavelength band and to the first frequency wavelength band;
a second chip region that comprises spaced apart ports and an active electrooptical component;
wherein the multiple chips regions form an alignment path and a transmission path, each path optically couples the multiple chip regions to each other, wherein an attenuation value of the alignment path is indicative of an alignment between the multiple chip regions.
wherein an ingress part of the alignment path comprises the first wavelength band input, the first wavelength band input, the first wavelength band coupler, the first combiner, the first WSC port, the third WSC port, a first WSC path between the first WSC port and the third WSC port, the intermediate chip region, a first port of the spaced apart ports;
wherein an egress part of the alignment path comprises a second port of the spaced apart ports, the intermediate chip region, the third WSC port, the first WSC path, the first WSC port, the first combiner, the first wavelength band coupler, and the first detector;
wherein an ingress part of the transmission path comprises a second wavelength band input, the first combiner, the first WSC port, the third WSC port, the first WSC path, the intermediate chip region, and the first port of the spaced apart ports;
wherein an egress part of the transmission path comprises the second port of the spaced apart ports, the intermediate chip region, the third WSC port, the second WSC path between the second WSC port and the third WSC port, and the second wavelength band output.

16. The multiple chip regions according to claim 15, wherein the egress part of the alignment path and the egress part of the transmission path further share a wavelength selective coupler (WSC).

17. The multiple chip regions according to claim 15, wherein the ingress part of the alignment path and the ingress part of the transmission path further share a wavelength selective coupler (WSC).

18. The multiple chip regions according to claim 17, wherein the ingress part of the alignment path and the ingress part of the transmission path share further share a circulator that couples a third WSC port of the WSC and each one of the spaced apart ports.

19. The multiple chip regions according to claim 17, wherein the transmission path and the alignment path share a circulator that optically couples the third WSC port and each one of the spaced apart ports.

20. The multiple chip regions to claim 15, wherein the first chip region is further adapted to output the processed second wavelength band optical signal to an ingress port of a transmission path formed within other multiple chip regions.
